(19) United States
(12) Patent Application Publication
(10) Pub. No.: US 2026/0324272 A1
(43) Pub. Date: Oct. 15, 2026

(54) ELECTRONIC DEVICE

(71) Applicant: Innolux Corporation, Miaoli County (TW)

(72) Inventor: Shuhei Hosaka, Miaoli County (TW)

(73) Assignee: Innolux Corporation, Miaoli County (TW)

(21) Appl. No.: 19/452,895

(22) Filed: Jan. 20, 2026

Related U.S. Application Data
(60) Provisional application No. 63/785,648, filed on Apr. 9, 2025.

(51) Int. Cl. H10K 59/88; H10H 29/49; H10K 59/131

(52) U.S. Cl. CPC H10K 59/88; H10H 29/49; H10K 59/131

(57) ABSTRACT

The present disclosure provides a substrate, a first mark, and a first wiring layer. The substrate has a first surface and a second surface opposite to the first surface in a first direction, wherein the first surface includes an active area where a device layer is disposed thereon. The first mark is disposed on the first surface and configured in the active area. The first wiring layer is disposed on the first surface and included in the device layer, wherein the first mark is visible when viewed from the second surface of the substrate.

### CROSS-REFERENCE TO RELATED APPLICATION

This application claims the priority benefit of U.S. provisional application serial no. 63/785,648, filed on Apr. 9, 2025. The entirety of the above-mentioned patent application is hereby incorporated by reference herein and made a part of this specification.

### BACKGROUND

### Technical Field

The present disclosure relates to an electronic device, and particularly relates to an electronic device including a display device.

### Description of Related Art

With the continuous progress of the technology industry, display devices have been extensively adopted in various products such as televisions, computers, and mobile phones. Recently, narrow-bezel displays have become a prevailing trend in the development of high-quality display devices due to their advantages of simplified appearance, enhanced aesthetics, and an increased display area in a given panel size. However, the arrangement of various components disposed in the display region is constrained by the limited space. Accordingly, there is a continuous need for further improvements in integrating certain components, which were originally arranged in the peripheral region, into the display region so as to satisfy current or future needs.

### SUMMARY

The present disclosure provides an electronic device in which a mark set (e.g., process related marks) is arranged in an active area of the electronic device, which is beneficial for increasing the horizontal area of the active area, and thus provides advantages to the borderless design.

According to an embodiment of the present disclosure, the electronic device includes a substrate, a first mark, and a first wiring layer. The substrate has a first surface and a second surface opposite to the first surface in a first direction, wherein the first surface includes an active area where a device layer is disposed thereon. The first mark is disposed on the first surface and configured in the active area. The first wiring layer is disposed on the first surface and is included in the device layer. The first mark is visible when viewed from the second surface of the substrate.

Based on the above, in the electronic device of the present disclosure in accordance with the embodiment, the first mark is designed to be disposed on the first surface, configured in the active area, and being visible when viewed from the second surface of the substrate, which is beneficial for increasing the horizontal area of the active area, and thus provides advantages to the borderless design. In addition, the first mark can be applied to process related marks when the first mark can be observed from the second surface of the substrate. Accordingly, reliability of the electronic device can be improved.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view illustrating an electronic device according to an embodiment of the present disclosure.

FIGS. 2A-2D are schematic cross-sectional views illustrating various electronic device according to different embodiments of the present disclosure.

FIG. 3 is an enlarged schematic top view illustrating a portion of an active area of an electronic device according to an embodiment of the present disclosure.

FIG. 4A is an enlarged schematic top view illustrating a portion of a pixel region of an electronic device according to an embodiment of the present disclosure.

FIG. 4B is an enlarged schematic top view illustrating a pixel unit configured in the pixel region of an electronic device according to an embodiment of the present disclosure.

FIG. 5 is a schematic view illustrating an electronic device according to an embodiment of the present disclosure.

FIG. 6 is a schematic view illustrating an electronic device according to another embodiment of the present disclosure.

FIG. 7 is a schematic top view illustrating an electronic device according to still another embodiment of the present disclosure.

FIG. 8 is a schematic cross-sectional view taken along line C-C’ in FIG. 7.

### DESCRIPTION OF THE EMBODIMENTS

The disclosure can be understood with reference to the following detailed description in conjunction with the accompanying drawings. It should be noted that, for ease of understanding by readers and for the concision of the illustration, a plurality of drawings in the disclosure only depict parts of the electronic device or the transistor, and certain elements in the drawings are not drawn according to the actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words such as “having” and “including” are open-ended words, and thus should be interpreted as the meaning of “including but not limited to.”

In this document, "one component is disposed on another component" is for convenience in describing the relative position between the said component and the said another component, and is not intended to limit the process steps or sequence between the said component and the said another component.

Directional terms mentioned herein, such as “up,” “down,” “front,” “rear,” “left,” “right,” and the like refer only to the directions of the drawings. Accordingly, the directional terms are used for illustration, and are not intended to limit the disclosure. It should be understood that when an element or a film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping with another element, the element or film layer at least partially overlaps with another element or film layer

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In some embodiments of the disclosure, terms related to bonding and connection, such as “connection,” “interconnection,” and the like, unless otherwise specified, may mean that two structures are in direct contact, or may also mean that two structures are not in direct contact, in which there are other structures provided between these two structures. The terms related to bonding and connection may also include the case where both structures are movable, or both structures are fixed. Furthermore, the terms “electrically connected” or “coupled” includes any direct and indirect means of electrical connection.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

In some embodiments of this disclosure, the thickness, length, and width may be obtained through a measurement using an optical microscope (OM). The thickness or the width may be obtained by measuring from a cross-sectional image in an electron microscope, but is not limited thereto.

The electronic device of this disclosure may be applied to a power module, a semiconductor package device, a display device, a light-emitting device, a back-light device, an antenna device (e.g., a liquid crystal antenna), a sensing device, a testing device or a tiled device, but is not limited thereto. The electronic device includes a rollable electronic device or a flexible electronic device. The display device may include, for example, a non-self-luminous panel such as a liquid crystal panel or other self-luminous panels, but is not limited thereto. The antenna device may be a liquid crystal type antenna device or a non-liquid crystal type antenna device, but is not limited thereto. The sensing device may be a sensing device for sensing capacitance, light, heat or ultrasound, but is not limited thereto. The tiled device may be, for example, a display tiled device or an antenna tiled device, but is not limited thereto. It should be understood that the electronic device may be any combination of the aforementioned arrangements, but is not limited thereto.

The exemplary embodiments of this disclosure are described in the following for example, and the same reference numerals used in the figures and descriptions are represented to the same or similar portions.

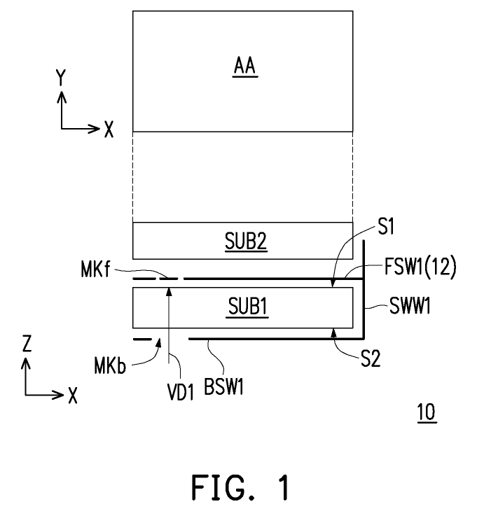

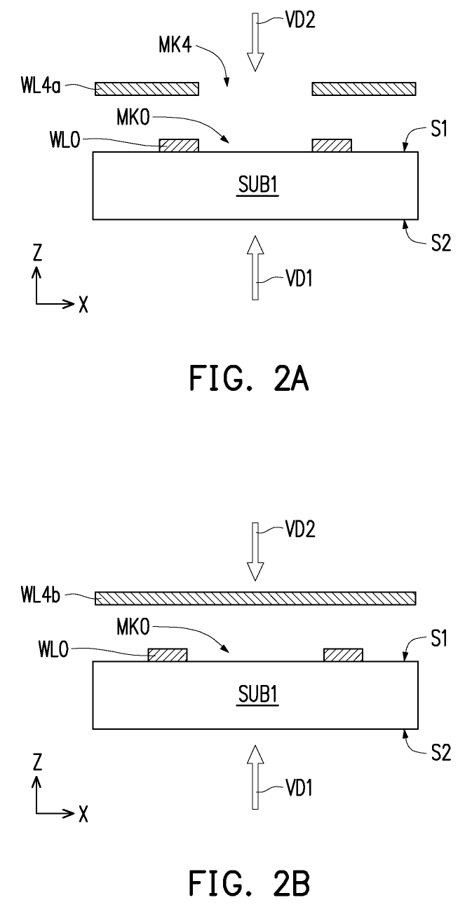

FIG. 1 is a schematic view illustrating an electronic device according to an embodiment of the present disclosure. FIGS. 2A-2D are schematic cross-sectional views illustrating various electronic device according to different embodiments of the present disclosure.

Referring to FIG. 1, an electronic device 10 is provided. In some embodiments, the electronic device 10 may be a display device including a substrate SUB1 and a substrate SUB2 above the substrate SUB1. The substrate SUB1 and the substrate SUB2 may be made of transparent materials such as glass. The substrate SUB1 may be an array substrate where a device layer 12 including active devices, passive devices, and conductive wirings is formed thereon. The active devices may include switching components such as transistors (e.g., thin film transistors (TFTs)) and light-emitting components such as a light emitting diode (LED), a quantum dot (QD), a fluorescence, a phosphor, other suitable materials, or combinations thereof. The passive devices may include capacitors, resistors, inductors, or combinations thereof. The light emitting diode may include, for example, an organic light emitting diode (OLED), a mini-LED, a micro-LED, or a quantum dot light emitting diode (QLED, QDLED), but is not limited thereto. The conductive wirings may include signal lines such as data lines, scan lines, or combinations thereof. The substrate SUB2 may be a color filter substrate where optical features such as red filters, green filters, blue filters, light-shielding layers, polarizing plates are formed thereon. In the illustrated embodiment as shown in FIG. 1, the substrate SUB1 includes a first surface S1 (e.g., a front surface) facing the substrate SUB2 and a second surface S2 (e.g., a rear surface) opposite to the first surface S1 in a first direction (e.g., Z direction).

Referring to FIG. 1, the electronic device 10 may be a borderless display device, that is, an active area AA where the device layer 12 is disposed thereon may have a horizontal area substantially equal to or slightly smaller than that of the first surface S1. In this case, drivers (e.g., gate drivers) and functional circuits (e.g., inspection circuits or electro-static discharge (ESD) protection circuits) that were originally configured in the peripheral region surrounding the active region are configured on the second surface S2 of the substrate SUB1. In the illustrated embodiment as shown in FIG. 1, such drivers and functional circuits disposed on the second surface S2 of the substrate SUB1 are electrically connected to the devices (e.g., TFT or LED) disposed on the first surface S1 of the substrate SUB1 through a back-side wiring layer BSW1 disposed on the second surface S2 of the substrate SUB1, a sidewall wiring layer SWW1 disposed on the side surface of the substrate SUB1, and a front-side wiring FSW1 disposed on the first surface S1 and included in the device layer 12. In the illustrated embodiment shown in FIG. 1, the sidewall wiring layer SWW1 is disposed on the side surface connecting the first surface S1 and the second surface S2 and electrically connects the backside wiring layer BSW1 to the front-side wiring FSW1. The back-side wiring layer BSW1, the sidewall wiring layer SWW1, and the front-side wiring FSW1 may include any suitable conductive material, such as copper (Cu), aluminum (Al), nickel (Ni), molybdenum (Mo), titanium (Ti), alloys or combinations of the above materials, or other suitable materials, but is not limited thereto.

Referring to FIG. 1, the electronic device 10 includes a first mark MKf disposed on the first surface S1 and configured in the active area AA. The first mark MKf is visible when viewed from the second surface S2 of the substrate SUB1 (e.g., along a viewing direction VD1), which is beneficial for controlling process accuracy. For example, the first mark MKf may be a process related mark used in LED bonding processes, LED repair processes, back-side wiring processes, sidewall wiring processes, or related inspections thereof. In some other embodiments, the first mark MKf may be visible when viewed from the first surface S1 of the substrate SUB1 (e.g., along a viewing direction opposite to the viewing direction VD1), which is beneficial for controlling process accuracy. For example, the first mark MKf may be a process related mark that is used to check the positions or alignments for the elements formed on the first surface S1 of the substrate SUB1. In some embodiments, the first mark MKf may be used in the processes such as LED transfer processes, LED inspection, LED bonding processes, LED repair processes, or mask-based processes, or may be used to check the pixel positions. The first mark MKf may be applied to other processes or inspections other than the aforementioned processes or inspection, the present disclosure is not limited thereto. In some embodiments, referring to FIG. 1, the first mark MKf may be a metal pattern integrated in a first wiring layer included in the front-side wiring FSW1. In some embodiments, the metal pattern for the first mark MKf may be electrically isolated from the first wiring layer included in the front-side wiring FSW1.

Referring to FIG. 1 the back-side wiring layer BSW1 is laterally distanced from the first mark MKf when viewed from the first direction (e.g., along the viewing direction VD1) so that the first mark MKf is visible when viewed from the second surface S2 of the substrate SUB1. In some embodiments, the backside wiring layer BSW1 may include a mark pattern MKb, and a composite mark constituted by the mark pattern MKb and the first mark MKf may be observed when viewed from the second surface S2 of the substrate SUB1. For example, the mark pattern MKb may be an opening pattern formed in the backside wiring layer BSW1 and overlapping with the first mark MKf, and a composite mark constituted by the opening pattern and the first mark MKf may be observed when viewed from the second surface S2 of the substrate SUB1.

Referring to FIGS. 1, 2A, and 2B, the front-side wiring FSW1 includes a first wiring layer WL0 disposed on the first surface S1 and included in the device layer 12. In the illustrated embodiment shown in FIG. 2A, the first mark MK0 is an opening pattern form in the first wiring layer WL0, and the first mark MK0 is visible when viewed from the second surface S2 of the substrate SUB1 (e.g., along a viewing direction VD1). In the illustrated embodiment shown in FIGS. 2A and 2B, the front-side wiring FSW1 further includes a second wiring layer WL4a or WL4b disposed over the first wiring layer WL0, wherein at least portion of the first mark MK0 is overlapped with the second wiring layer WL4a or WL4b in the first direction (e.g., Z direction). Referring to FIG. 2A, in the case where the second wiring layer WL4a includes a second mark MK4, the second mark MK4 is visible when viewed from the first surface S1 of the substrate SUB1 (e.g., along a viewing direction VD2), and the first mark MK0 is visible when viewed from the second surface S2 of the substrate SUB1. In some embodiments, the first mark MK0 and the second mark MK4 may be opening patterns having the same contour when viewed from the first direction. Referring to FIG. 2B, the first mark MK0 is visible when viewed from the second surface S2 of the substrate SUB1, while the first mark MK0 is invisible when viewed from the first surface S1 of the substrate SUB1 since the first mark MK0 is covered by the second wiring layer WL4b.

Referring to FIGS. 1 and 2C, the front-side wiring FSW1 includes a second wiring layer WL4c disposed over the first wiring layer WL0, wherein the first mark MK0 is disposed between the substrate SUB1 and the second wiring layer WL4c. Referring to FIG. 2C, in the case where the second wiring layer WL4c is laterally distanced from the first mark MK0 when viewed from the first direction (e.g., Z direction), so that the first mark MK0 is visible when viewed from both the first surface S1 and the second surface S2 of the substrate SUB1. Referring to FIGS. 1 and 2D, the front-side wiring FSW1 may include a second wiring layer WL4d disposed over the substrate SUB1 and including a second mark MK4 formed in a region of the substrate SUB1 where the first wiring layer WL0 is not formed, so that the second mark MK4 is visible when viewed from both the first surface S1 and the second surface S2 of the substrate SUB1.

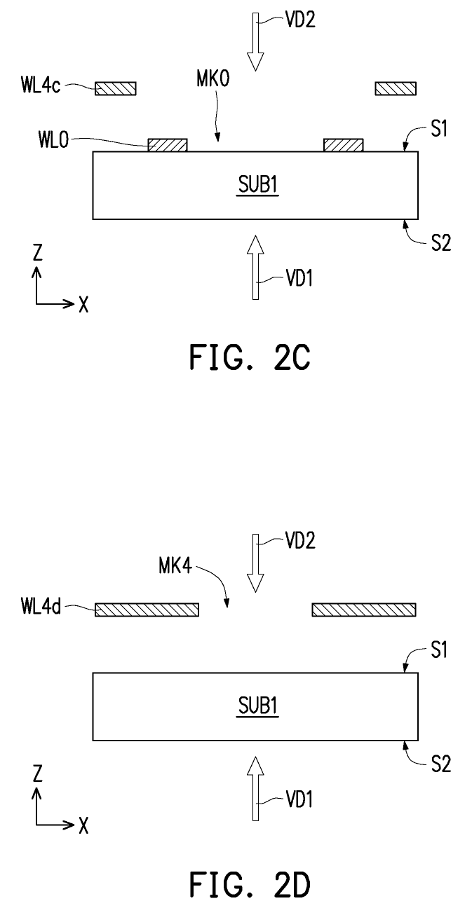

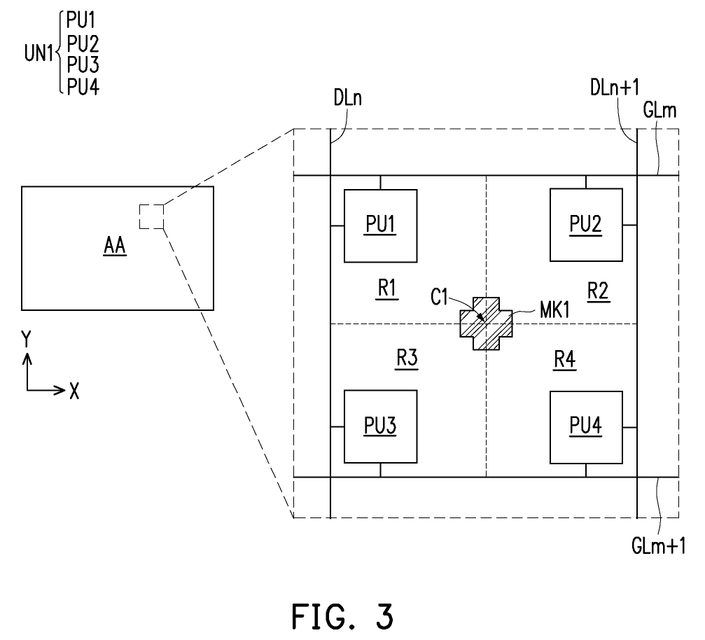

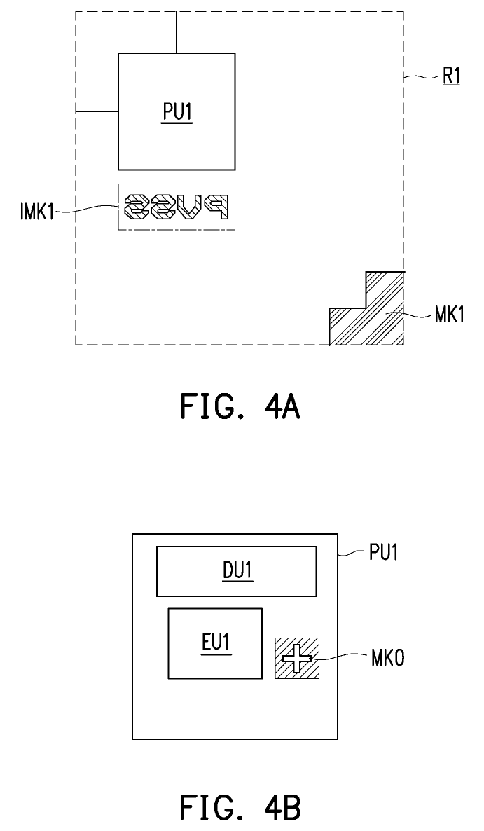

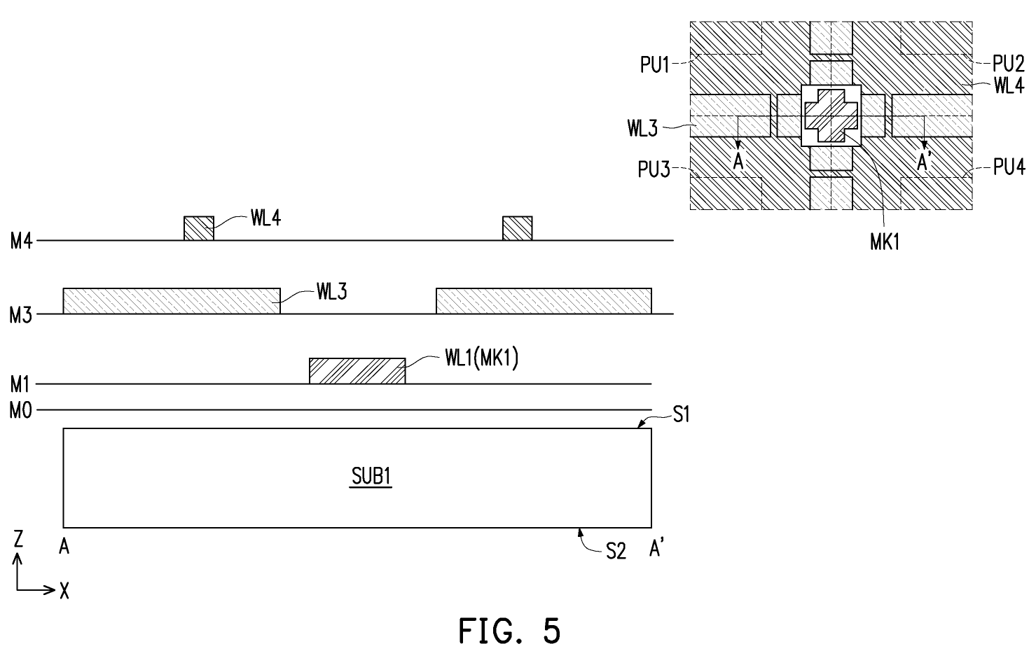

FIG. 3 is an enlarged schematic top view illustrating a portion of an active area of an electronic device according to an embodiment of the present disclosure. FIG. 4A is an enlarged schematic top view illustrating a portion of a pixel region of an electronic device according to an embodiment of the present disclosure. FIG. 4B is an enlarged schematic top view illustrating a pixel unit configured in the pixel region of an electronic device according to an embodiment of the present disclosure. FIG. 5 is a schematic view illustrating an electronic device according to an embodiment of the present disclosure. FIG. 6 is a schematic view illustrating an electronic device according to another embodiment of the present disclosure.

In some embodiments, referring to FIGS. 2A and 3, the electronic device 10 may include a repeating unit UN1 including the pixel units PU1, PU2, PU3, and PU4 respectively located in regions R1, R2, R3, and R4 of the active area AA. In this embodiment, the first wiring layer WL0 or the second wiring layer WL4a disposed over the first wiring layer WL0 may include signal lines DLn, DLn+1, GLm and GLm+1 electrically coupled to pixel units PU1, PU2, PU3, and PU4 arranged in an array in the active area AA. In some embodiments, the signal lines DLn and DLn+1 may be conductive wires extending along the Y direction, and the signal lines GLm and GLm+1 may be conductive wires extending along the X direction. The conductive wires may be made of the conductive materials as mentioned above, and are not be repeated herein. In some embodiments, the signal lines DLn and DLn+1 may be data lines electrically connected to the pixel units PU1, PU2, PU3, and PU4, and the signal lines GLm and GLm+1 may be scan lines electrically connected to the pixel units PU1, PU2, PU3, and PU4. The pixel units PU1, PU2, PU3, and PU4 may include driving units and light-emitting unit connecting to the driving units. For example, as shown in FIG. 4B, the pixel unit PU1 includes a driving unit DU1 and a light-emitting unit EU1 connecting to the driving unit DU1. The driving unit DU1 may include switching components (e.g., TFT) configured to control the driving power supplied to the light-emitting unit EU1. The light-emitting unit EU1 may include, for example, an organic light emitting diode (OLED), a mini-LED, a micro-LED, or a quantum dot light emitting diode (QLED, QDLED), but is not limited thereto.

Referring to FIGS. 3, 4A and 4B, the electronic device 10 may include a mark MK1 configured at the center C1 of the repeating unit UN1, a mark IMK1 configured in the region R1 where the pixel unit PU1 is disposed, and a mark MK0 arranged adjacent to the light-emitting unit EU1 or a driving unit DU1 included in at least one of the pixel units (e.g., pixel unit PU1). In some embodiments, the mark MK1 may be a process related mark (e.g., an alignment mark) arranged between the pixel units PU1, PU2, PU3 and PU4 and used in the processes for manufacturing the pixel units PU1, PU2, PU3 and PU4, the mark IMK1 may be an identifying mark for the pixel unit PU1, and the mark MK0 may be a process related mark (e.g., an alignment mark) used in the process for manufacturing the driving unit DU1 and the light-emitting unit EU1, but the disclosure is not limited thereto.

In some embodiments, the mark MK1 and the mark MK0 may be configured in different wiring levels of the front-side wiring FSW1. For example, referring to FIG. 5 and FIG. 6, the front-side wiring FSW1 may include a wiring layer WL0 configured at a wiring level M0, a wiring layer WL1 configured at a wiring level M1 over the wiring level M0, a wiring layer WL3 configured at a wiring level M3 over the wiring level M1, and a wiring layer WL4 configured at a wiring level M4 over the wiring level M3. The mark MK1 is integrated in the wiring layer WL1 configured at the wiring level M1, the mark MK0 is integrated in the wiring layer WL0 configured at the wiring level M0. The wiring layer ML4 may include a mark MK4 configured at the wiring level M4. In some embodiments, the mark MK0 and the mark MK4 may be opening patterns having the same contour (e.g., cross-shaped contour) when viewed from the first direction (e.g., Z direction). In the illustrated embodiment shown in FIGS. 6 and 5, the wiring layer WL4 is disposed over the wiring layer WL1 and includes the mark MK4, wherein the mark MK1 is a metal pattern integrated in the wiring layer WL1, and the mark MK4 is an opening pattern (e.g., cross-shaped opening pattern shown in FIG. 6) formed in the wiring layer WL4.

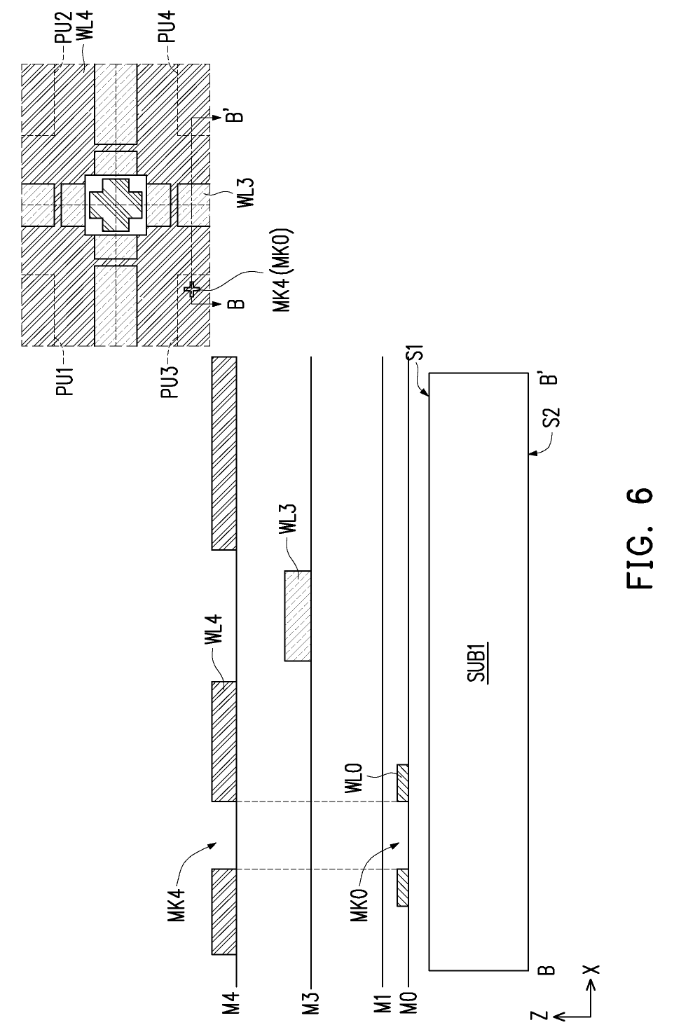

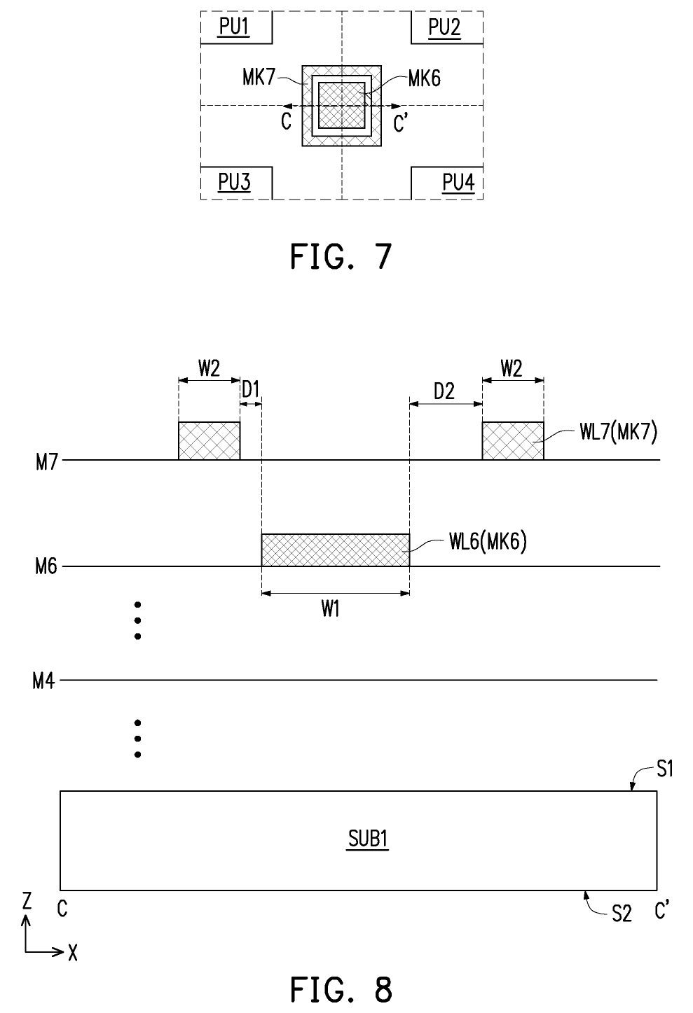

FIG. 7 is a schematic top view illustrating an electronic device according to still another embodiment of the present disclosure. FIG. 8 is a schematic cross-sectional view taken along line C-C’ in FIG. 7. The electronic device 10 may include a mark MK6 integrated in the wiring layer WL6 configured at the wiring level M6, and a mark MK7 integrated in the wiring layer WL7 configured at the wiring level M7 over the wiring level M6. In the illustrated embodiment shown in FIGS. 7 and 8, the mark MK6 may be a first metal pattern integrated in the wiring layer WL6, and the mark MK7 may be a second metal pattern integrated in the wiring layer WL7 and surrounding the first metal pattern and laterally distanced from the first metal pattern when viewed from the first direction (e.g., Z direction). In some embodiments, the first metal pattern of the mark MK6 includes a first side and a second side opposite to each other in a second direction (e.g., X direction) perpendicular to the first direction, the second metal pattern of the mark MK7 includes an inner side surrounding the first metal pattern of the mark MK6 when viewed from the first direction, and when viewing from the first direction, the first side and the second side are distanced from the inner side by different distances in the second direction. For example, as shown in FIG. 8, the distance D1 is different from the distance D2. In some embodiments, the distance D1 and the distance D2 may be adjusted by adjusting the width W1 of the first metal pattern of the mark MK6 and/or the width W2 of the second metal pattern of the mark MK7.

In summary, in the electronic device described in the above embodiments, the first mark is designed to be disposed on the first surface, configured in the active area, and being visible when viewed from the second surface of the substrate, which is beneficial for increasing the horizontal area of the active area, and thus provides advantages to the borderless design. In addition, the first mark can be applied to process related marks when the first mark can be observed from the second surface of the substrate. Accordingly, reliability of the electronic device can be improved.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. An electronic device, comprising:
a substrate having a first surface and a second surface opposite to the first surface in a first direction, wherein the first surface comprises an active area where a device layer is disposed thereon; and
a first mark disposed on the first surface and configured in the active area; and
a first wiring layer disposed on the first surface and comprised in the device layer,
wherein the first mark is visible when viewed from the second surface of the substrate.

2. The electronic device of claim 1, wherein the first mark is an opening pattern formed in the first wiring layer.

3. The electronic device of claim 1, wherein the first mark is a metal pattern integrated in the first wiring layer.

4. The electronic device of claim 3, wherein the first mark is electrically isolated from the first wiring layer.

5. The electronic device of claim 1, further comprising:
a backside wiring layer disposed on the second surface of the substrate, wherein the backside wiring layer is laterally distanced from the first mark when viewed from the first direction.

6. The electronic device of claim 5, further comprising:
a sidewall wiring layer disposed on a side surface of the substrate and electrically connecting the backside wiring layer to the first wiring layer, wherein the side surface connects the first surface and the second surface.

7. The electronic device of claim 5, wherein the backside wiring layer comprises an opening pattern overlapping the first mark, and a composite mark constituted by the opening pattern and the first mark is observed when viewed from the second surface of the substrate.

8. The electronic device of claim 1, wherein the first mark is visible when viewed from both the first surface and the second surface of the substrate.

9. The electronic device of claim 8, further comprising:
a second wiring layer disposed over the first wiring layer, wherein the first mark is disposed between the substrate and the second wiring layer.

10. The electronic device of claim 9, wherein the second wiring layer is laterally distanced from the first mark when viewed from the first direction.

11. The electronic device of claim 1, further comprising:
a second wiring layer disposed over the first wiring layer, and wherein at least portion of the first mark is overlapped with the second wiring layer in the first direction.

12. The electronic device of claim 11, wherein the second wiring layer comprises a second mark, and the second mark is visible when viewed from the first surface of the substrate.

13. The electronic device of claim 12, wherein the first mark and the second mark are opening patterns having the same contour when viewed from the first direction.

14. The electronic device of claim 11, wherein the first mark is invisible when viewed from the first surface of the substrate.

15. The electronic device of claim 1, further comprising:
a second wiring layer disposed over the first wiring layer and comprising signal lines electrically coupled to pixel units arranged in an array in the active area.

16. The electronic device of claim 15, wherein the first mark is arranged adjacent to a light-emitting unit or a driving unit included in at least one of the pixel units.

17. The electronic device of claim 15, wherein the first mark is arranged between the pixel units.

18. The electronic device of claim 1, further comprising:
a second wiring layer disposed over the first wiring layer and comprising a second mark, wherein the first mark is a metal pattern integrated in the first wiring layer, and the second mark is an opening pattern formed in the second wiring layer.

19. The electronic device of claim 1, further comprising:
a second wiring layer disposed over the first wiring layer and comprising a second mark, wherein the first mark comprises a first metal pattern integrated in the first wiring layer, and the second mark is a second metal pattern surrounding the first metal pattern and laterally distanced from the first metal pattern when viewed from the first direction.

20. The electronic device of claim 19, wherein the first metal pattern comprises a first side and a second side opposite to each other in a second direction perpendicular to the first direction, the second metal pattern comprises an inner side surrounding the first metal pattern when viewed from the first direction, and
when viewing from the first direction, the first side and the second side are distanced from the inner side by different distances in the second direction.
